(19) United States
(12) Patent Application Publication
(10) Pub. No.: US 2026/0182334 A1
(43) Pub. Date: Jun. 25, 2026

(54) APPARATUS INCLUDING TSV AND MULTIPLE INSULATING MATERIALS

(71) Applicant: MICRON TECHNOLOGY, INC., BOISE, ID (US)

(72) Inventor: Tomohiko Kudo, Higashi Hiroshima-shi (JP)

(73) Assignee: MICRON TECHNOLOGY, INC., Boise, ID (US)

(21) Appl. No.: 19/422,703

(22) Filed: Dec. 17, 2025

Related U.S. Application Data
(60) Provisional application No. 63/736,547, filed on Dec. 19, 2024.

(51) Int. Cl. H10W 20/20; H10W 20/42

(52) U.S. Cl. CPC H10W 20/2134; H10W 20/42

(57) ABSTRACT

Some embodiments of the disclosure provide an apparatus comprising: a first metal layer including a first wiring surrounded by a low-k dielectric layer (e.g., SiOC); a second metal layer including a second wiring above the first metal layer surrounded by another low-k dielectric layer (e.g., SiOC); an insulating layer (e.g., SiCN) between the first and second metal layers; a TSV including at least a top part thereof reaching the insulating layer; and a via provided in the insulating layer and configured to couple the first and second wirings. At least the top part of the TSV is provided at the same layer level as the via. The insulating layer includes a first insulating layer on the first metal layer to prevent diffusion of a metal material of the first wiring, and a second insulating layer above the first layer to prevent diffusion of a metal material of the TSV.

### CROSS-REFERENCE TO RELATED APPLICATIONS

This application claims the filing benefit of U.S. Provisional Application No. 63/736,547, filed Dec. 19, 2024. This application is incorporated by reference herein in its entirety and for all purposes.

### BACKGROUND

High data reliability, high speed of memory access, lower power consumption, and reduced chip size are features that are demanded from semiconductor memory devices. A three-dimensional (3D) memory device may be formed by stacking a plurality of memory dies (or memory chips) and interconnecting the stacked memory dies using a plurality of through-silicon vias (TSVs). Benefits of the 3D memory device include shorter interconnects which reduce signal delays and power consumption, a greater number of vertical vias between layers which allow wide bandwidth buses between functional blocks in different layers, and a considerably smaller footprint. Thus, the 3D memory device contributes to higher memory access speed, lower power consumption, and chip size reduction. Example 3D memory devices include a High Bandwidth Memory (HBM) DRAM and a Hybrid Memory Cube (HMC) DRAM.

### BRIEF DESCRIPTION OF THE DRAWINGS

FIGS. 1A and 1B depict at least part of an example apparatus in a vertical cross-sectional view and a horizontal cross-sectional view, respectively, according to some embodiments of the disclosure.

FIG. 1C is an example graph showing time dependent dielectric breakdown (TBBD).

FIGS. 2A-2C depict example processes of manufacturing an example apparatus in a cross-sectional view according to some embodiments of the disclosure.

FIG. 3 depicts a schematic configuration of an example semiconductor system according to an embodiment of the disclosure.

FIG. 4 is a block diagram of an example semiconductor device according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

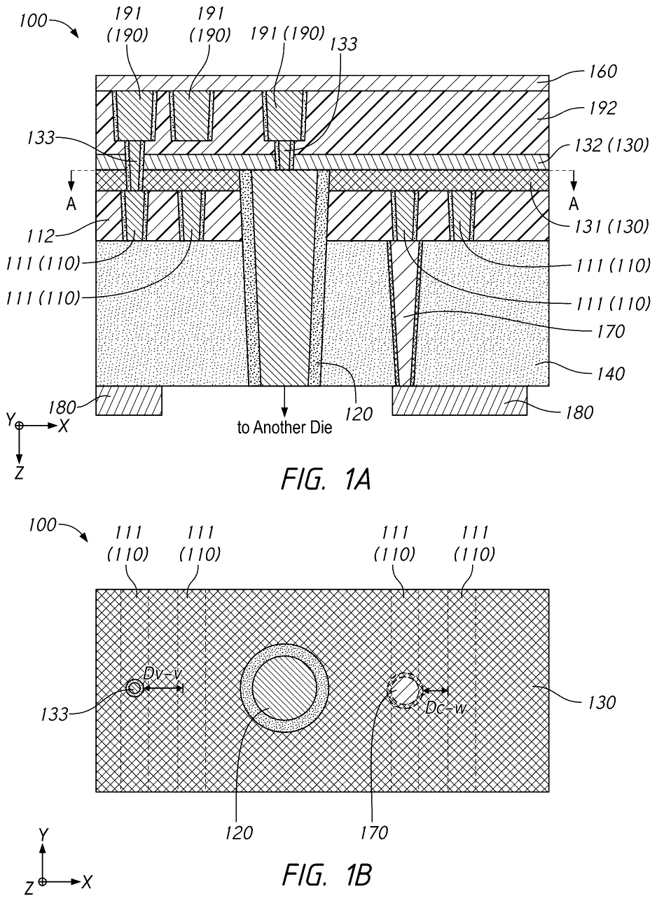

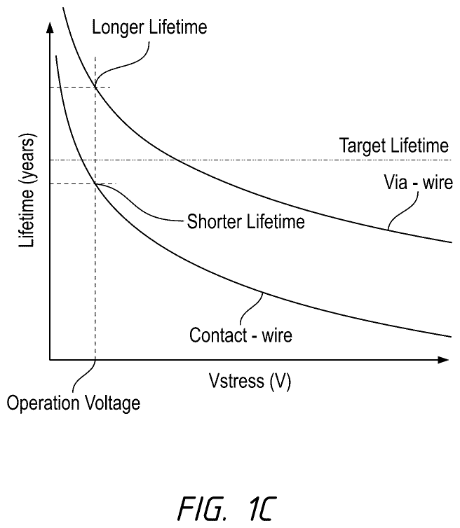

FIG. 1A depicts at least part of an example apparatus 100 in a vertical cross-sectional view according to some embodiments of the disclosure. FIG. 1B depicts at least part of the example apparatus 100 in a horizontal cross-sectional view at an A-A line in FIG. 1A according to some embodiments of the disclosure. The apparatus 100 may be a semiconductor device. The apparatus 100 may be a memory device, such as a dynamic random-access memory (DRAM). The apparatus 100 may be a logic device. The apparatus 100 according to the present embodiments includes a first metal layer 110 including one or more first wirings 111, a second metal layer 190 including one or more second wirings 191 above the first metal layer 110, and an insulating layer 130 between the first metal layer 110 and the second metal layer 190. The apparatus 100 further includes one or more vias 133 in the insulating layer 130, which couple corresponding ones of the first wirings 111 and corresponding ones of the second metal wirings 191. The apparatus 100 further includes a through-silicon via (TSV) 120 having at least a top part thereof reaching the insulating layer 130 where the vias 133 are provided. The TSV 120 sticks out into the insulating layer 130. The apparatus 100 still further includes another via 133 above the TSV 120.

The plurality of wirings 111 in the first metal layer 110 are arranged in parallel with each other in a first horizontal direction (for example, an x-axis direction in the drawing) and each extend in a second horizontal direction (for example, a y-axis direction in the drawing) orthogonal to the first horizontal direction. The plurality of wirings 111 may be metal wirings. The plurality of wirings 111 may be interconnects. The metal wiring layer 110 may be provided above another metal wiring layer 180 on a semiconductor substrate. The layer 180 may be a lower metal layer, and the layer 110 may be an upper metal layer. In some embodiments, the lower metal layer 180 and the upper metal layer 110 may be referred to as, for example, Mx and Mx+1 (where x=0, 1, 2, . . . ), respectively. In some embodiments, the metal layer 180 may be a local interconnect layer, which may also be referred to as Ly (where y=0, 1, 2, . . . ). In some embodiments, the lower metal layer or the local interconnect layer may be coupled to transistors in a semiconductor substrate. In some embodiments, the metal layer 110 may be provided above a semiconductor substrate where transistors are formed. In the depicted example, the wirings 111 are surrounded by or embedded in an insulating layer 112. The insulating layer 112 is provided on another insulating layer 140, which is provided on the lower metal layer 180. The insulating layer 112 may include an insulating material, such as a low-k dielectric material. The low-k dielectric material may include for example silicon oxycarbide (SiOC). The insulating layer 140 may include an insulating material, such as silicon dioxide (SiO₂). The wirings 111 in the metal layer 110 may be coupled to corresponding wirings in a lower metal layer, a local interconnect layer, or the like, such as the metal layer 180, by corresponding vertical contacts 170 that are provided in the insulating layer 140 extending in the z-axis direction. The contacts 170 may include a conductive material, such as tungsten (W). In the depicted example, only one contact 170 is provided to couple one of the wirings 111 to the lower metal layer 180. In other instances, there may be one or more contacts 170 coupling the corresponding wirings 111 to the lower metal layer 180.

In a similar manner to the wirings 111 in the first metal layer 110, the plurality of wirings 191 in the second metal layer 190 are arranged in parallel with each other in the first horizontal (x-axis) direction and each extend in the second horizontal (y-axis) direction. The plurality of wirings 191 may be arranged above the corresponding wirings 111 in alignment and coupled to the corresponding wirings 111 by corresponding vias 133. The vias 133 are described in further detail below. The plurality of wirings 191 may be interconnects. In some embodiments, the layer 190 above the layers 180 (Mx) and 110 (Mx+1) may be referred to as Mx+2. In the depicted example, the layer 190 and thus the wirings 191 are surrounded by or embedded in an insulating layer 192. The insulating layer 192 may include an insulating material, such as a low-k dielectric material. The low-k dielectric material may include for example silicon oxycarbide (SiOC). In the depicted example, the apparatus 100 may include still another insulating layer 160 on the insulating layer 192. The insulating layer 160 may include an insulating material, such as silicon carbonitride (SiCN). The insulating layer 160 may be a barrier layer to prevent diffusion of a conductive material, such as copper (Cu), of the wirings 111. In some embodiments, there may be further provided vertical contacts, metal wiring layers, interconnects, or the like above the depicted configuration (for example, on the insulating layer 160) in a semiconductor device such as a semiconductor memory device and a semiconductor logic device.

The TSV 120 is arranged extending in a vertical direction (for example, a z-axis direction in the drawing). At least a top part of the TSV 120 reaches the insulating layer 130 and extends midway in the insulating layer 130. In the depicted example, at least part of the TSV 120 extends through the insulating layers 140 and 112. In some embodiments, a bottom part of the TSV 120 may be coupled to another wiring or conductive layer. In some embodiments, the TSV 120 may extend through semiconductor substrates of first and second dies stacked on one another and couple wirings or interconnects in the first die to wirings or interconnects in the second die under the first die. In the case of a memory device, such as a DRAM, the dies connected by one or more TSVs may include core memory dies and an interface (IF) die.

In the depicted example, the insulating layer 130 includes a first layer (may also be referred to as a first insulating layer) 131 on the first metal layer 110 and a second layer (may also be referred to as a second insulating layer) 132 above the first layer 131. The first layer 131 covers at least a top part of each of the first wirings 111. The second layer 132 covers at least a top part of the TSV 120. The first layer 131 may be a first barrier layer to prevent diffusion of a conductive material, such as copper (Cu), of the first wirings 111 from a top surface of each of the first wirings 11. The second layer 132 may be a second barrier layer to prevent diffusion of a conductive material, such as copper (Cu), of the TSV 120 from a top surface of the TSV 120. The first and second layers 131 and 132 of the insulating layer 130 may include an insulating material, such as silicon carbonitride (SiCN). The TSV 120 extends midway in the insulating layer 130. The TSV 120 sticks out into the insulting layer 130. The TSV 120 has the top part thereof reaching a border between the first layer 131 and the second layer 132 of the insulting layer 130. The TSV 120 extends through the first layer 131, protrudes from a top surface of the first layer 131, and reaches a bottom surface of the second layer 132. In some embodiments, the core conductive part of the TSV 120 may have at least on side surfaces thereof an insulating film or a dielectric film as a liner, including for example a nitride, an oxide, or a combination thereof. Similarly, the core conductive part of each of the wirings 111 may have at least on side thereof a liner, including for example a nitride, an oxide, or a combination thereof. The formation of the first and second layers 131 and 132 of the insulating layer 130 that cover at least the top parts (that are not protected by the liners) of the wirings 111 and the TSV 120 are described in further detail below.

The apparatus 100 of the present embodiments further includes vias 133 extending through the first and second layers 131 and 132 of the insulating layer 130 and reaching the first wiring 111 under the first layer 131 and the second wiring 191 above the second layer 132. The vias 133 are surrounded by the insulating layer 130. In the depicted example, only one via 133 is provided coupling the first and second wirings 111 and 191. In other instances, there may be one or more vias 133 coupling the corresponding first and second wirings 111 and 191. In the depicted example, the second wiring 191 stops midway in the insulating layer 192 in the z-axis direction; hence, a top part of the via 133 further extends through part of the insulating layer 192 above the second layer 132 of the insulating layer 130, and reaches a bottom part of the corresponding second wiring 191 in the insulating layer 192. On the other side, a bottom part of the via 133 reaches and is coupled to a top part of the corresponding first wiring 111 under the first layer 131 of the insulating layer 130. In some embodiments, the second wiring 191 may extend all the way to the bottom of the insulating layer 192, and in such a case, the via 133 may meet with and be coupled to the second wiring 191 at the border of the insulating layer 192 and the second layer 132 of the insulating layer 130. In the depicted example, another via 133 is provided on the TSV 120 and couples the TSV 120 to the second wiring 191. A top part of this via 133 extends through the second layer 132 of the insulating layer 130 from a top part of the TSV 120 and reaches a bottom part of a corresponding second wiring 191 provided above the TSV 120. A bottom part of the via 133 is coupled to the top part of the TSV 120. In some embodiments, the second wiring 191 above the TSV 120 may extend all the way to the bottom of the insulating layer 192, and in such a case, the via 133 may meet with and be coupled to the second wiring 191 at the border of the insulating layer 192 and the second layer 132 of the insulating layer 130.

In the apparatus 100 according to the present embodiments, the TSV 120 is provided such that at least the top part thereof reaches and extends midway in the insulating layer 130 at the same layer level as the vias 133. The apparatus 100 can effectively improve the time dependent dielectric breakdown (TDDB) characteristic, and hence can further the longevity of a semiconductor device, such as a memory device and a logic device, in comparison with a case where a TSV reaches only a lower metal layer, such as the metal layer 110 where the wirings 111 are provided. More specifically, for example, if the TSV 120 reaches only the metal layer 110, then the insulating layer 130 (e.g., an SiCN layer) will be provided at the same layer level as the metal layer 110 above the insulating layer 140. In such a configuration, the distance Dc-w (see FIG. 1B) between the vertical contact 170 in the insulating layer 140 and the neighbor wiring 111 of the metal layer 110 surrounded by the insulating layer 130 may be short. This may cause a shorter TDDB lifetime (see the curve denoted as “Contact-wire” in FIG. 1C). On the other hand, in the configuration according to the present embodiments where the TSV 120 is formed at least at the same layer level as the via 133, in other words, the insulating layer 130 (e.g., an SiCN layer) used for the TSV formation and for the TSV conductive material diffusion protection is provided at the same layer level as the layer where the via 133 is provided above the metal layer 110, the distance Dv-w (see FIG. 1B) between the via 133 surrounded by the insulating layer 130 and the neighbor wiring 111 of the metal layer 110 may be longer. Therefore, Dv-w>Dc-w. This can exhibit a longer TDDB lifetime (see the curve denoted as “Via-wire” in FIG. 1C) than the former configuration. Thus, the via 133 becomes more sustainable at least in terms of requiring a longer time to reach a breakdown point than the wiring 111 when the same operational voltage stress (Vstress) is applied to the via 133 and the wiring 111. In other words, if the same lifetime is to be expected, the via 133 can withstand a greater Vstress over the years than the wiring 111. Furthermore, in the configuration according to the present embodiments, as illustrated in FIG. 1C, both the via 133 and the wiring 111 can achieve a predetermined target lifetime.

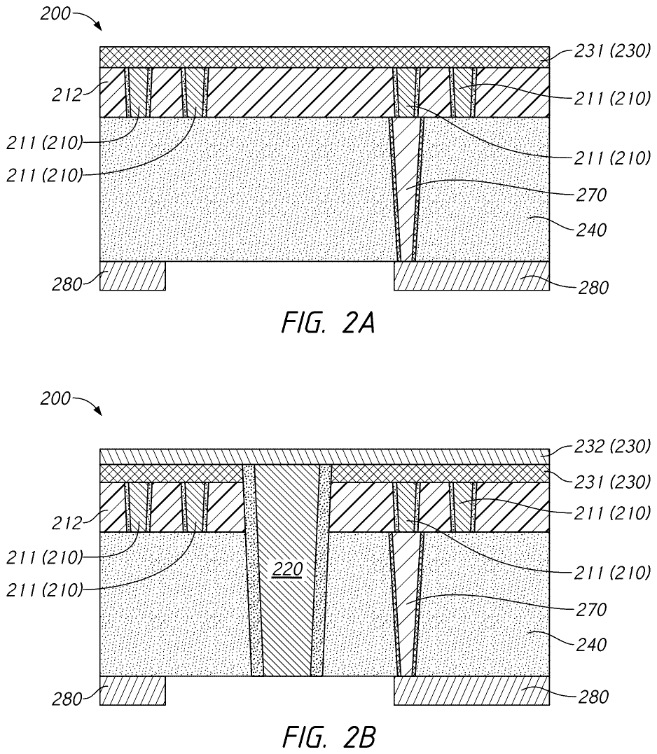

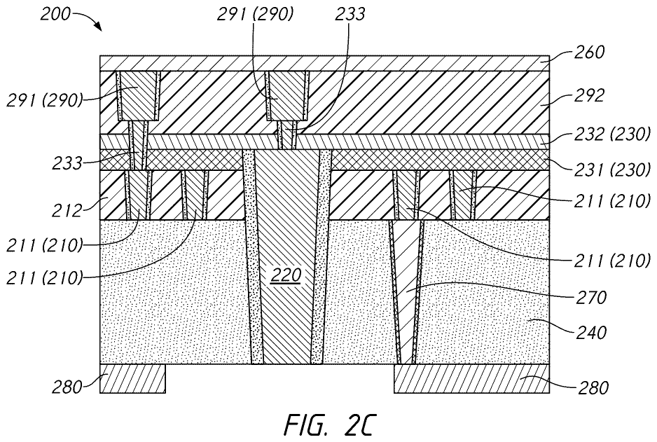

FIGS. 2A-2C depict example processes of manufacturing an example apparatus 200 in a cross-sectional view according to some embodiments of the disclosure. The apparatus 200 may correspond to the apparatus 100 in FIG. 1. Sizes, positions, and the like of the components of the apparatus 200, however, may not be the same as those of the apparatus 100.

As shown in FIG. 2A, a metal layer 210 (e.g., 110 in FIG. 1A) including a plurality of wirings 211 (e.g., 111 in FIG. 1A) are formed in an insulating layer 212 (e.g., 112 in FIG. 1A) above a lower insulating layer 240 (e.g., 140 in FIG. 1A). The plurality of wirings 211 may be formed by conventional methods, such as photolithography, dry etching, chemical vapor deposition (CVD), and chemical-mechanical polishing (CMP), as appropriate. Furthermore, a first layer 231 of an insulating layer 230 (e.g., 131 and 130 in FIG. 1A) is formed on the insulating layer 212 and the metal layer 210, covering at least an exposed top surface of each of the wirings 211. The first layer 213 of the insulating layer 230 may include an insulating material, such as SiCN. In the insulating layer 240, some vertical contacts 270 (e.g., 170 in FIG. 1A) are also provided to couple the corresponding wirings 111 to corresponding wirings in a lower metal layer 280 (e.g., 180 in FIG. 1A). As one example, the vertical contacts 270 may first be formed in the insulating layer 240, and after forming the insulating layer 212 on the insulating layer 240, the wirings 211 may be formed in the insulating layer 212 at the corresponding positions with the vertical contacts 270. In the depicted example, only one contact 270 is illustrated; however, one or more contacts 270 may be formed at appropriate positions, coupling the corresponding wirings 211 to the lower metal layer 280.

As shown in FIG. 2B, a TSV 220 (e.g., 120 in FIG. 1A) is then formed by conventional methods, such as photolithography, dry etching, CVD, and CMP, as appropriate. The TSV 220 extends through the insulating layers 240 and 212 and through the first layer 231 of the insulating layer 230. After the TSV is formed, the exposed surface of the TSV 220 is polished by for example CMP together with the surface of the first layer 231 of the insulating layer 230. After this process, a second layer 232 (e.g., 132 in FIG. 1A) is formed covering at least an exposed top part of the TSV 220 by appropriate conventional methods. The first layer 231 of the insulating layer 230 is thus used for the TSV formation and is left on the first metal layer 210 as a barrier layer to prevent diffusion of the wiring conductive material. The second layer 232 of the insulating layer 230 is then formed on the first layer 231 as a barrier layer to prevent diffusion of the TSV conductive material. The resultant configuration has the TSV 220 extending midway in the insulating layer 230 and reaching at least the border between the first layer 231 and the second layer 232 of the insulating layer 230.

Subsequently, as shown in FIG. 2C, by using appropriate conventional methods, such as photolithography, dry etching, chemical vapor deposition, and chemical-mechanical polishing, an insulating layer 292 (e.g., 192 in FIG. 1A) is formed on the insulating layer 230, vias 233 (e.g., 130 in FIG. 1) are formed penetrating through the insulating layer 230 and partially through the insulating layer 292, an upper metal layer 290 including wirings 291 (e.g., 190 and 191 in FIG. 1A) is then formed in the insulating layer 230, coupled to the corresponding vias 233, and an insulating layer 260 (e.g., 160 in FIG. 1A) is formed on the insulating layer 292, covering top surfaces of the wirings 291. Similarly to the example configuration in FIG. 1A, the via 233 and the wiring 211 are also formed above the TSV 220. This via 233 extends through the second layer 232 of the insulating layer 230 and partially the insulating layer 292, and couples the TSV 220 and the corresponding wiring 211. The apparatus 200 fabricated according to the present embodiments exhibits the improved TDDB characteristic with the TSV 220 having at least the top part thereof formed in the insulating layer 230 at the same layer level as the vias 233, and hence improves the longevity of a semiconductor device.

In FIGS. 1A-2C, the TSVs 120-220 are depicted adjacently to the contacts 170-270 and the first wirings 111. According to some embodiments of the disclosure, for example, in the case of a memory device, such as a DRAM, the contacts 170-270 and the first wirings 111 as well as the corresponding vias 133-233 and second wirings 191-291 may be provided in a memory array region where memory cells and various circuits, such as sense amplifiers and sub-word line drivers, are arranged on each die, whereas the TSVs 120-220 may be provided in a designated TSV region in each of dies stacked on one another to couple the stacked dies, such as core dies and an interface die.

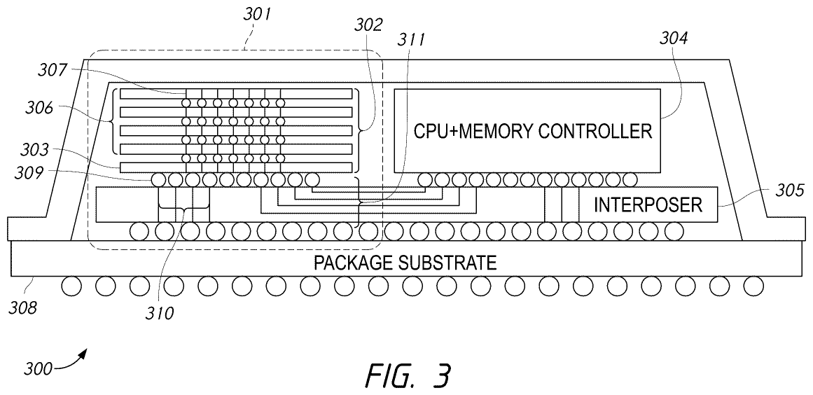

FIG. 3 depicts a schematic configuration of an example semiconductor system 300 according to some embodiments of the disclosure. The semiconductor system 300 may include an apparatus, which may be for example the apparatuses 100-200. The semiconductor system 300 includes a semiconductor memory device 301 in some embodiments of the disclosure. The semiconductor system 300 may also include a central processing unit (CPU) and memory controller 304, which may be a controller chip, on an interposer 305 on a package substrate 308. The interposer 305 may include one or more power lines 310 which may supply power supply voltage from the package substrate 308. The interposer 305 may include a plurality of channels 311 that may interconnect the CPU and memory controller 304 and the semiconductor memory device 301. The semiconductor memory device 301 may be a dynamic random access memory (DRAM). The memory controller 304 may provide a clock signal, a command signal, and may further transmit and receive data signals. The plurality of channels 311 may transmit the data signals between the memory controller and the memory device 301. The semiconductor memory device 301 may include a plurality of dies (or chips) 302 including at least one interface (IF) die (or chip) 303 and a plurality of memory core dies (or chips) 306 stacked with each other. A number of the memory core dies 306 may not be limited to four as in the illustrated example, and may be more or fewer as appropriate. Each of the memory core dies 306 may include a plurality of memory cells and circuitries accessing the memory cells. For example, the memory cells may be DRAM memory cells. The memory cells may be arranged in array. The semiconductor memory device 301 may include conductive vias 307 (such as the TSVs 120-220 in some embodiments of the disclosure) which couple the IF die 303 and the memory core dies 306 by penetrating the IF die 303 and the memory core dies 306. The IF die 303 may be coupled to the interposer 305 via interconnects 309. For example, the interconnects 309 may be microbumps having bump pitches of less than about or less than one hundred micrometers and exposed on an outside of the IF die 303. A portion of each of the interconnects 309 may be coupled to the one or more power lines 310. Another portion of each of the interconnects 309 may be coupled to one or more of the channels 311.

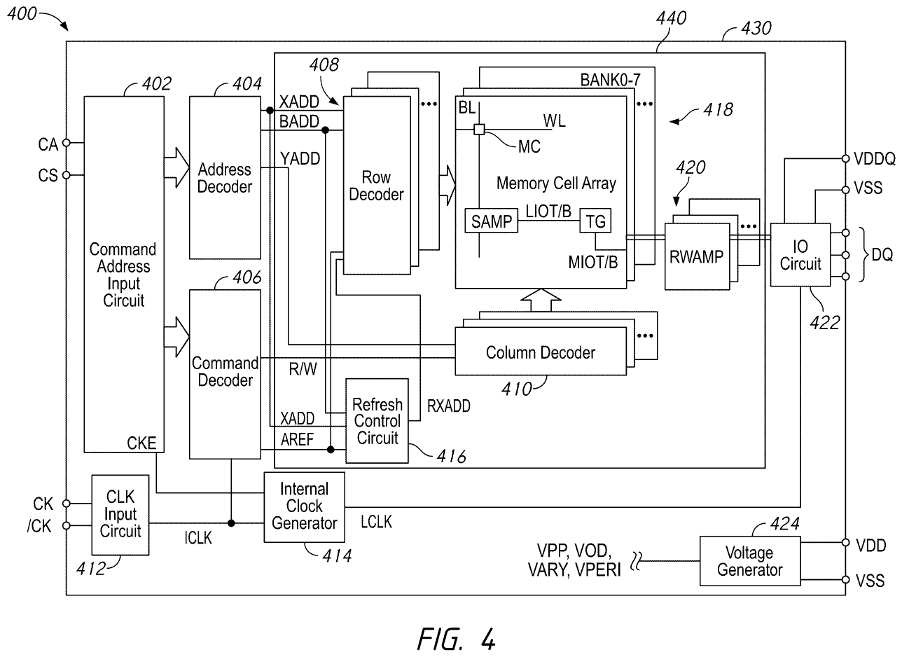

FIG. 4 is a block diagram of an example semiconductor device 400 according to some embodiments of the disclosure. The semiconductor device 400 may be a semiconductor memory device, such as a dynamic random-access memory (DRAM) device. The DRAM device may include an interface die and a plurality of core dies which are stacked on the interface die. In the example diagram of FIG. 4, certain components are shown located on an interface (IF) die 430, while other components are shown as part of each of core dies 440. For the sake of clarity, only a single core die 440 and its components are shown; however, there may be multiple core dies (e.g., 2, 4, 6, 8, 16, or more) each with similar components to each other. The example semiconductor device 400 of FIG. 4 shows a particular arrangement of components between the IF die 430 and the core die 440; however, other arrangements may be used in other embodiments. For example, a refresh control circuit 416 may be on the IF die 430 in some embodiments. For the sake of illustration, the core die 440 is drawn as a rectangular box which is smaller than the IF 430; however, the core die 440 and IF die 430 may have any size relationship to each other. For example, the core die 440 and IF die 430 may be approximately the same size. The IF die 430 may include or may be part of a logic die. In other embodiments, the bottom core die of the stacked core dies may take a role of an interface as a master chip, and the upper core dies may act as slave chips to receive control information from and transmit data to the bottom core die.

The semiconductor device 400 includes a memory array 418 on each of the core dies 440. The memory array 418 is shown as including a plurality of memory banks. In the embodiments of FIG. 4, the memory array 418 is shown as including eight memory banks BANK0-BANK7. More or fewer banks may be included in the memory array 418 of other embodiments. Each memory bank includes a plurality of word lines WL, a plurality of bit lines BL, and a plurality of memory cells MC arranged at intersections of the plurality of word lines WL and the plurality of bit line BL. Selection of the word line WL is performed by a row decoder 408 and selection of the bit lines BL is performed by a column decoder 410, each of which may also be located on each of the core dies 440. In the embodiments of FIG. 4, the row decoder 408 includes a respective row decoder for each memory bank and the column decoder 410 includes a respective column decoder for each memory bank. The bit lines BL are coupled to a respective sense amplifier (SAMP) of the memory array 418. Read data from the bit line BL is amplified by the sense amplifier SAMP, and transferred to read/write amplifiers (RWAMPs) 420 over complementary local data lines (LIOT/B), transfer gate (TG), and complementary main data lines (MIOT/B) which are coupled to RWAMP 420. Conversely, write data outputted from RWAMP 420 is transferred to the sense amplifier SAMP over the complementary main data lines MIOT/B, the transfer gate TG, and the complementary local data lines LIOT/B, and written in the memory cell MC coupled to the bit line BL.

The semiconductor device 400 may employ a plurality of external terminals located on the IF die 430 or the bottom core die. The external terminals may include command and address (CA) terminals coupled to a command and address bus to receive commands and addresses and a chip select (CS) signal, clock terminals to receive clocks CK and /CK, data terminals DQ to provide data, and power supply terminals to receive power supply potentials VDD, VSS, and VDDQ.

The clock terminals are supplied with external clocks CK and /CK that are provided to an input circuit 412. The external clocks CK and /CK may be complementary. The input circuit 412 generates an internal clock ICLK based on the CK and /CK clocks. The ICLK clock is provided to the command decoder 406 and to an internal clock generator 414. The internal clock generator 414 provides various internal clocks LCLK based on the ICLK clock. The LCLK clocks may be used for timing operation of various internal circuits. The internal clocks LCLK are provided to an input and output (IO) circuit 422 to time operation of circuits included in the IO circuit 422, for example, to data receivers to time the receipt of write data. In some embodiments, the internal clocks LCLK may include a read clock which is used to control the timing of read operations, and a write clock which is used to control the timing of write operations. In some embodiments, the internal clocks may be passed to the IO circuit 422. In some embodiments, the internal clocks may also be passed to internal components, such as RWAMP 420, of the core die 440.

The CA terminals may be supplied with memory addresses. The memory addresses supplied to the CA terminals are transferred, via a command/address input circuit 402, to an address decoder 404. The address decoder 404 receives the address and supplies a decoded row address XADD to the row decoder 408 and supplies a decoded column address YADD to the column decoder 410. The address decoder 404 may also supply a decoded bank address BADD, which may indicate the bank of the memory array 418 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 406 via the command/address input circuit 402. The command decoder 406 includes circuits to decode the internal command signals to generate various internal signals and commands for performing operations. For example, the command decoder 406 may provide a row command signal to select a word line and a column command signal to select a bit line.

The semiconductor device 400 may receive an access command which is a read command. When a read command is received, and a bank address, a row address and a column address are timely supplied with an activate command and the read command, read data is read from memory cells in the memory array 418 corresponding to the row address and column address. The read command is received by the command decoder 406, which provides internal commands so that the read data from the memory cells in the memory array 418 is provided to RWAMP 420. The read data is output to outside the semiconductor device 400 from the data terminals DQ via the IO circuit 422.

The semiconductor device 400 may receive an access command which is a write command. When the write command is received, and a bank address, a row address and a column address are timely supplied with an activate command and the write command, write data is supplied through the DQ terminals to RWAMP 420. The write data supplied to the data terminals DQ is written to the memory cells in the memory array 418 corresponding to the row address and column address. The write command is received by the command decoder 406, which provides internal commands so that the write data is received by data receivers in the IO circuit 422. Write clocks may also be provided to the external clock terminals for timing the receipt of the write data by the data receivers of the IO circuit 422. The write data is supplied via the IO circuit 422 to RWAMP 420.

The semiconductor device 400 may also receive commands causing it to carry out one or more refresh operations as part of a self-refresh mode. In some embodiments, the self-refresh mode command may be externally issued to the semiconductor device 400. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 424. The internal voltage generator circuit 424 generates various internal potentials such as VPP, VOD, VARY, VPERI, and the like based on the power supply potentials VDD and VSS.

The power supply terminals are also supplied with power supply potential VDDQ. The power supply potential VDDQ is supplied to the IO circuit 422. The power supply potential VDDQ may be the same potentials as the power supply potential VDD in one instance. The power supply potential VDDQ may be different potentials from the power supply potential VDD in another instance. The power supply potential VDDQ are used for the IO circuit 422 so that power supply noise generated by the IO circuit 422 does not propagate to the other circuit blocks.

DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a first metal layer including a first wiring;
a second metal layer including a second wiring above the first metal layer;
an insulating layer between the first metal layer and the second metal layer;
a via provided in the insulating layer and configured to couple the first wiring and the second wiring; and
a through-silicon via (TSV) including at least a top part thereof reaching the insulating layer where the via is provided.

2. The apparatus according to claim 1, wherein the TSV extends midway in the insulating layer.

3. The apparatus according to claim 1, wherein the insulating layer including:
a first layer on the first metal layer, configured to cover at least a top part of the first wiring; and
a second layer above the first layer, configured to cover at least the top part of the TSV.

4. The apparatus according to claim 3, wherein
the first layer is a first barrier layer to prevent diffusion of a conductive material of the first wiring, and
the second layer is a second barrier layer to prevent diffusion of a conductive material of the TSV.

5. The apparatus according to claim 3, wherein the TSV reaches the second layer above the first metal layer.

6. The apparatus according to claim 3, wherein the via extends through the first and second layers of the insulating layer and reaches the first wiring under the first layer and the second wiring above the second layer.

7. The apparatus according to claim 1, wherein the via is surrounded by the insulating layer.

8. The apparatus according to claim 7, wherein the insulating layer comprises silicon carbonitride (SiCN).

9. The apparatus according to claim 7, wherein the first wiring is surrounded by a first low-k dielectric layer under the insulating layer.

10. The apparatus according to claim 9, wherein the second wiring is surrounded by a second low-k dielectric layer above the insulating layer.

11. The apparatus according to claim 1, wherein the first wiring is coupled to another wiring in another metal layer under the first metal layer by a contact.

12. The apparatus according to claim 1, wherein the TSV couples a first die to a second die under the first die.

13. The apparatus according to claim 1, wherein the apparatus includes a memory device or a logic device.

14. An apparatus, comprising:
a first metal layer including a first wiring;
a second metal layer including a second wiring above the first metal layer;
an insulating layer between the first metal layer and the second metal layer;
a via provided in the insulating layer and configured to couple the first wiring and the second wiring; and
a through-silicon via (TSV) including at least a top part that reaches midway in the insulating layer and is provided at a same layer level as the via, wherein
the insulating layer includes:
a first insulating layer on the first metal layer, configured to cover at least a top part of the first wiring to prevent diffusion of a metal material of the first wiring; and
a second insulating layer above the first insulating layer, configured to cover at least the top part of the TSV to prevent diffusion of a metal material of the TSV.

15. The apparatus according to claim 14, wherein the via extends through the first and second insulating layers and reaches the first wiring under the first insulating layer and the second wiring above the second insulating layer.

16. The apparatus according to claim 14, wherein the apparatus further comprises low-k dielectric layer where the first wiring is provided under the insulating layer, and another low-k dielectric layer where the second wiring is provided above the insulting layer.

17. The apparatus according to claim 16, wherein the insulating layer comprises silicon carbonitride (SiCN), and the low-k dielectric layers comprise silicon oxycarbide (SiOC).

18. An apparatus, comprising:
a first metal wiring in a first layer;
a second metal wiring in a second layer above the first layer;
a via in a third layer between the first layer and the second layer, the via configured to couple the first metal wiring and the second metal wiring;
a through-silicon via (TSV) including at least a top part thereof in the third layer, wherein
the third layer includes an insulating layer as a barrier layer of the TSV.

19. The apparatus according to claim 18, wherein
the insulating layer and the barrier layer are a first insulating layer and a first barrier layer, respectively, and
the third layer further includes a second insulating layer under the first insulating layer as a second barrier layer of the first metal wiring.

20. The apparatus according to claim 19, wherein the top part of the TSV penetrates the second insulating layer and reaches the first insulating layer, and is covered by the first insulating layer.
